(19) United States
(12) Patent Application Publication
(10) Pub. No.: US 2003/0107120 A1
(43) Pub. Date: Jun. 12, 2003

(54) Intelligent motor drive module with injection molded package

(75) Inventors: Glyn Connah, Glossop (GB); George W. Pearson, Crawley Down (GB); Mark Steers, Crawley (GB)

Correspondence Address: OSTROLENK FABER GERB & SOFFEN, 1180 AVENUE OF THE AMERICAS, NEW YORK, NY, 100368403

(73) Assignee: International Rectifier Corporation

(21) Appl. No.: 10/317,285

(22) Filed: Dec. 10, 2002

Related U.S. Application Data
(60) Provisional application No. 60/339,158, filed on Dec. 11, 2001.

(51) Int. Cl. H01L 23/52

(52) U.S. Cl. 257/691

(57) ABSTRACT

A power module having a lead frame with a plurality of power switching devices and a plurality of driving devices mounted thereon. The driving devices control the power switching devices to provide power to a plurality of output leads via first wire bonds. The first wire bonds are substantially parallel to each other between the power switching devices and the output leads. Each power switching device preferably includes a power semiconductor device and a diode, the diodes and power switching devices being interconnected by second wire bonds which are also substantially parallel to each other. The power switching devices preferably comprise bare semiconductor die mounted on the lead frame, the lead frame and power switching devices being enclosed in a molded package. The molded package are preferably formed by transfer-molding or injection-molding.

### CROSS-REFERENCE TO RELATED APPLICATION

This application is based on and claims priority of U.S. Provisional Patent Application Serial No. 60/339,158, filed Dec. 11, 2001, the disclosures of which are incorporated by reference herein.

### BACKGROUND OF THE INVENTION

The application relates to a power module, and more particularly to a power module for housing a motor control circuit.

### BACKGROUND AND SUMMARY OF DISCLOSURE

Intelligent power modules (IPMs) are well known devices for driving various types of motors. These devices at minimum include a plurality of power switching devices and respective integrated circuits (ICs) for controlling the devices. Due to their high degree of integration IPMs provide for, among other advantages, reduced design time and improved reliability, and generally more compact sizes.

Most IPMs use insulated metal substrates (IMS) or direct bonded copper (DBC) substrates. These elements are expensive and thus add to the overall cost of the IPM. Thus, it is desirable to have a solution that improves the cost of an IPM while taking advantage of its other qualities.

According to a comparative example of an IPM described herein, an IMS is used as a substrate in an IPM which includes a plurality of power switching devices and respective ICs for driving the switches.

According to another highly advantageous example, the various elements of the IPM are disposed on a lead frame, and encapsulated in a molded housing. The use of the lead frame greatly reduces the cost and improves the manufacturing efficiency of the device.

In each of these examples, the respective output connections (wire bonds) from the switching devices corresponding to the three phases are separated. They are arranged such that they do not cross each other. Advantageously, the output wire bonds are arranged substantially parallel with each other. This separation and/or parallel arrangement of the output wire bonds reduces coupling between the phases and thus reduces unwanted spikes and crosstalk.

According to yet another example, the power switching devices are disposed on a portion of the substrate that is close to a major external surface of the IPM, preferably about 0.5 mm, or 20 mils. This proximity improves heat dissipation and thus avoids a requirement for a heat sink, thereby further reducing the cost of the IPM. On the other hand, the control side does not need to be displaced to a location close to an external surface, which advantageously improves the ability to support the lead frame on at least three sides.

The IPMs described herein are provided with a molded housing and can be used for driving a switched reluctance motor or a three phase motor.

Other features and advantages of the present invention will become apparent from the following description of embodiments of the invention which refers to the accompanying drawings.

### BRIEF DESCRIPTION OF THE DRAWINGS

FIG. 1 shows a diagram of a motor control circuit for driving a three-phase motor.

FIG. 1A shows a diagram of a circuit that drives a winding of a switched-reluctance motor.

FIG. 2 shows the exterior of an integrated circuit package for driving power semiconductor switches.

FIG. 2A is a functional block diagram of the package shown in FIG. 2.

FIG. 3 is a comparative example of a power module for driving a three-phase motor.

FIG. 4 is an example of a power module incorporating a lead frame for driving a three-phase motor.

FIG. 5 is a comparative example of a power module for driving a switched-reluctance motor.

FIG. 6 shows the exterior of a power module in a package form.

FIG. 7 is a side cross-sectional view showing an arrangement of a modified lead frame which provides improved heat dissipation.

### DETAILED DESCRIPTION OF EMBODIMENTS OF THE INVENTION

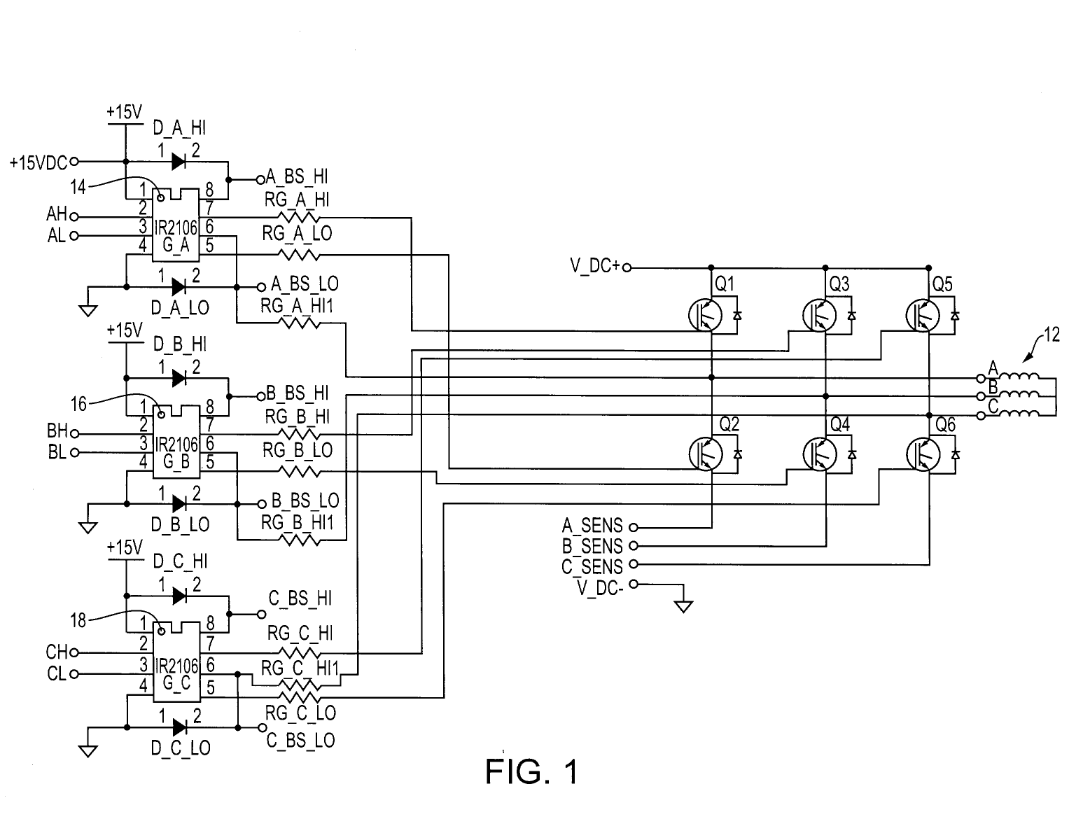

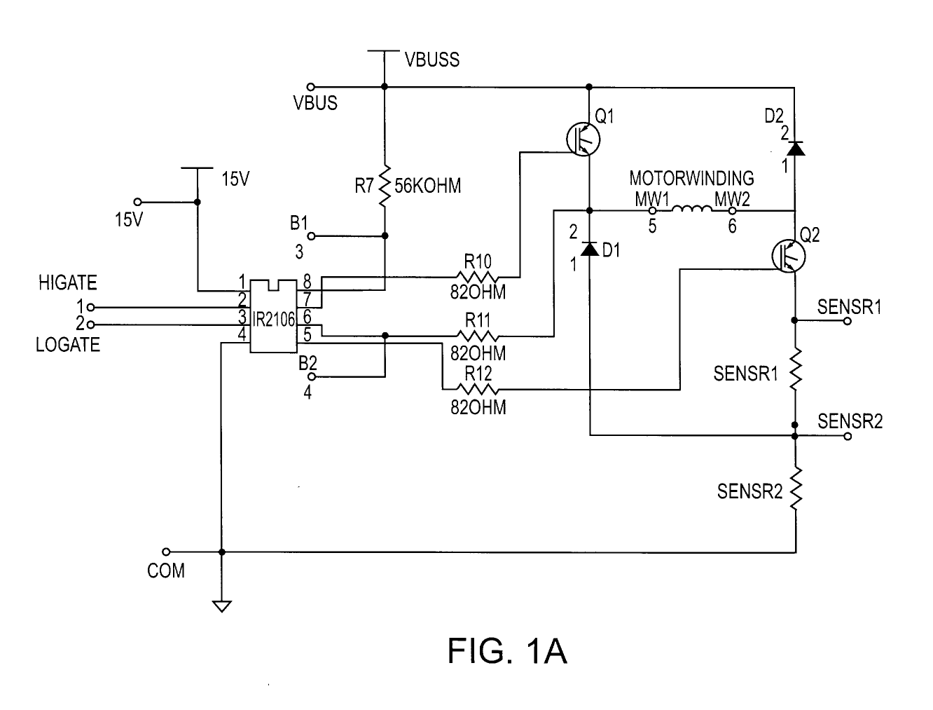

FIG. 1 shows a motor control circuit 10 for controlling a three-phase motor 12. Motor control circuit 10 includes three phase-control circuits each for controlling a phase winding A, B, C of three-phase motor 12. Each phase-control circuit includes a power stage, which may comprise two series-connected power semiconductor devices (e.g., Q₁-Q₂ pair; Q₃-Q₄ pair; Q₅-Q₆ pair), and power semiconductor driver circuits 14, 16, 18. The power semiconductor devices may be MOS-gated devices such as MOSFETs or IGBTs. Power semiconductor driver circuits 14, 16, 18 may be integrated circuits having drivers with independent high and low side referenced output channels. One such integrated circuit is provided by International Rectifier, the assignee of this application, and sold under the designation IR2106.

FIG. 1A shows a circuit diagram for driving a motor winding MW1-MW2 of a switched-reluctance motor, which may also be incorporated in a power module as will be described in relation to one of the forthcoming examples. The power semiconductor driver circuit again is the International Rectifier IR 2106.

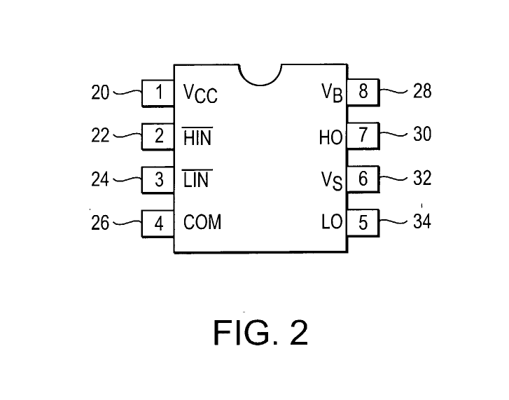

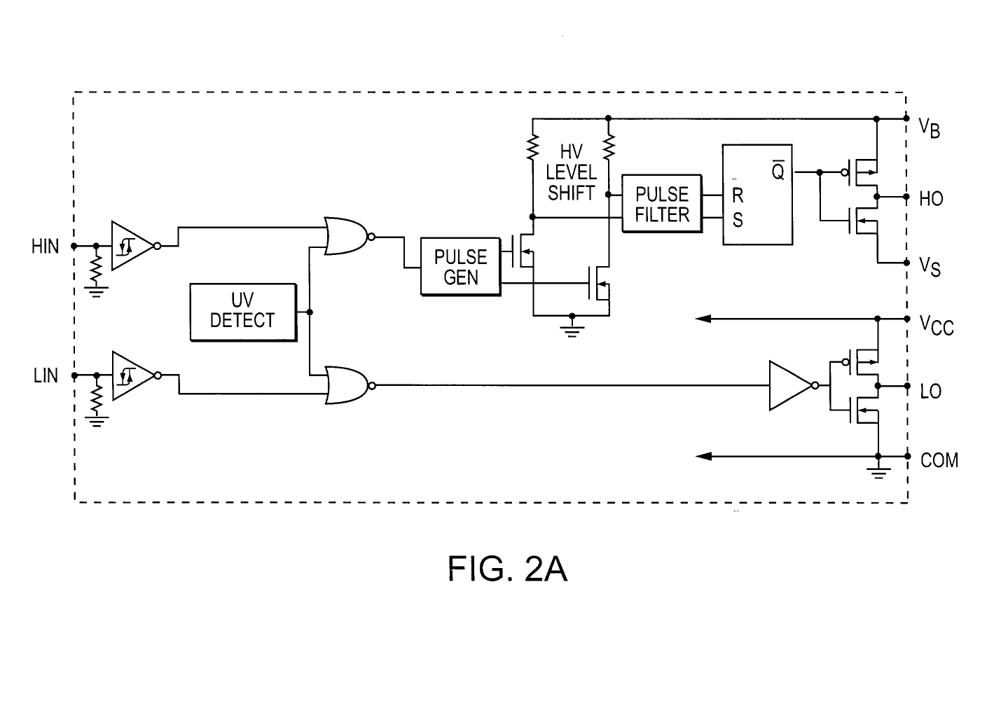

Referring to FIG. 2, each power semiconductor driver circuit 14, 16, 18 includes low side and logic fixed supply lead 20, logic input for high-side gate driver output lead 22, logic input for low-side gate driver output lead 24, low-side return lead 26, high-side floating supply lead 28, high-side gate driver output lead 30, high-side floating supply return 32 and low-side gate driver output lead 34.

FIG. 2A shows a functional block diagram of power semiconductor driver circuit 14, 16, 18 including the various lead connections.

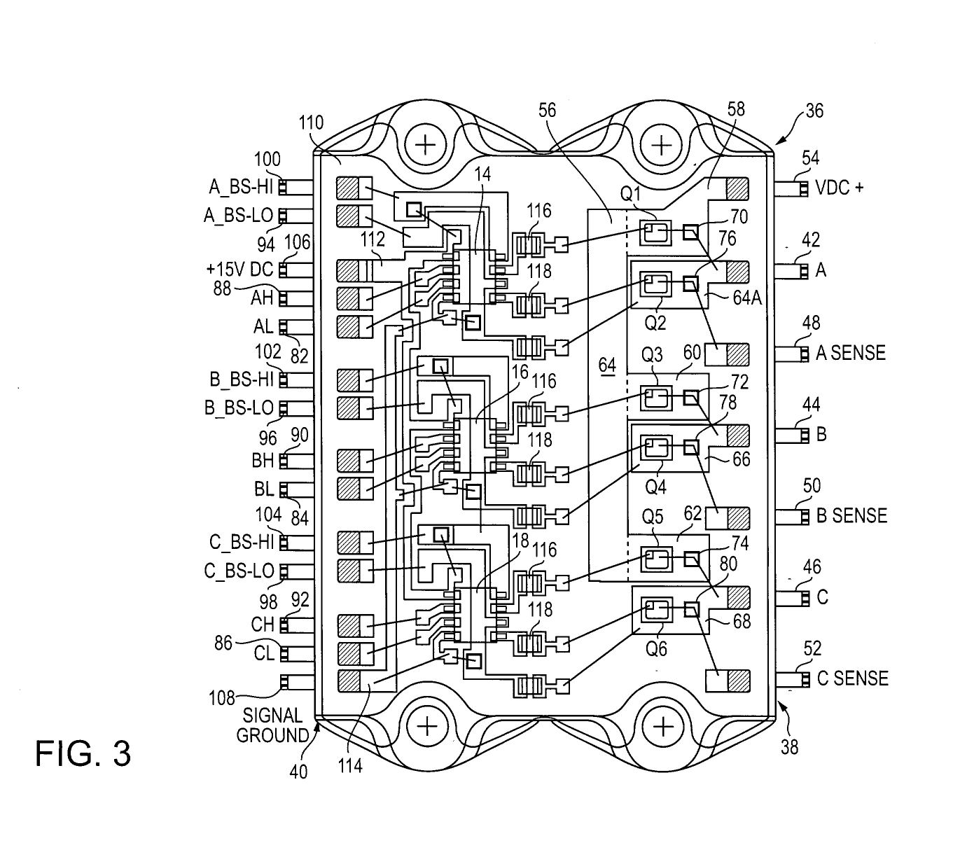

FIG. 3 shows a comparative example of a power module 36 for housing a motor control circuit. In this example, two rows of external leads are provided on opposing first and second sides 38, 40 of power module 36. Each row includes a respective set of leads associated with a corresponding one of the three phase-control circuits in the motor control circuit that is housed in power module 36. One row of leads positioned on first side 38 of power module 36 includes sets of leads, wherein each set includes a power lead 42, 44, 46 for connecting to a respective winding of three-phase motor 12 (FIG. 1), and a sensor lead 48, 50, 52. Bus lead 54 is connected to common conductive portion 56 which is disposed on IMS 110. High-side power semiconductor switches Q₁, Q₃, Q₅ are disposed on parallel extensions 58, 60, 62 that extend from connector portion 64 of common conductive portion 56. Connector portion 64 is substantially parallel to first side 38 of power module 36, and thus, parallel extensions 58, 60, 62 of common conductive portion 56 extend substantially perpendicular to first side 38 of power module 36.

Each one of low side power semiconductor switches Q₂, Q₄, Q₆ is disposed on and electrically connected to an isolated conductive patch 64A, 66, 68 disposed on IMS 110. Each isolated conductive patch 64A, 66, 68 is substantially parallel to a respective parallel extension 58, 60, 62 and connected to a respective power lead 42, 44, 46.

Bootstrap diodes 70, 72, 74 are disposed on parallel extensions 58, 60, 62, respectively, along with their respective high-side power semiconductor switches Q₁, Q₃, Q₅; while, bootstrap diodes 76, 78, 80 are disposed on isolated conductive patches 64A, 66, 68, respectively, along with their respective low-side power semiconductor switches Q₂, Q₄, Q₆. Appropriate circuit connections are made using bond wires, as shown in FIG. 3.

The second row of leads disposed at second side 40 of power module 36, which opposes its first side 38, includes sets of leads, wherein each set includes a low-side lead 82, 84, 86 and a high-side lead, 88, 90, 92. Low-side leads 82, 84, 86 are external connections for providing gate signals to respective low-side power semiconductor switches, Q₂, Q₄, Q₆; while high-side leads 88, 90, 92 are external connections for providing gate signals to respective high-side power semiconductor switches Q₁, Q₃, Q₅. Each set of leads includes a low sensor lead 94, 96, 98, and a high sensor lead 100, 102, 104. Each one of low sensor leads 94, 96, 98 is a connection leading to a sensor circuit for sensing the current through the low-side semiconductor devices Q₂, Q₄, Q₆, while each one of high sensor leads 100, 102, 104 is a connection leading to a sensor circuit for sensing the current through the high-side semiconductor devices Q₁, Q₃, Q₅.

Drive signal lead 106 and ground signal lead 108 are also disposed on second side 40 of power module 36. Drive signal lead 106, which is the electrical connection to the drive signal source (not shown), is connected to common drive signal runner 112.

Low-side and logic fixed supply lead 20 (FIG. 2) of each power semiconductor driver integrated circuit 14, 16, 18 (FIG. 1) is connected to common drive signal runner 112, and common ground runner 114 is connected to ground signal lead 108. Low-side return lead 26 (FIG. 2) of each power semiconductor driver circuit 14, 16, 18 (FIG. 1) is connected to a land on flexible circuit board 110, which is connected via a bond wire to common ground signal runner 114. High gate drive output lead 30 (FIG. 2) and low-side gate driver output lead 34 (FIG. 2) for each power semiconductor driver circuit 14, 16, 18 (FIG. 1) is connected to a respective gate electrode of a corresponding one of the high-side power semiconductor switches Q₁, Q₃, Q₅ or the low-side power semiconductor switches Q₂, Q₄, Q₆, each through a respective resistor 116, 118.

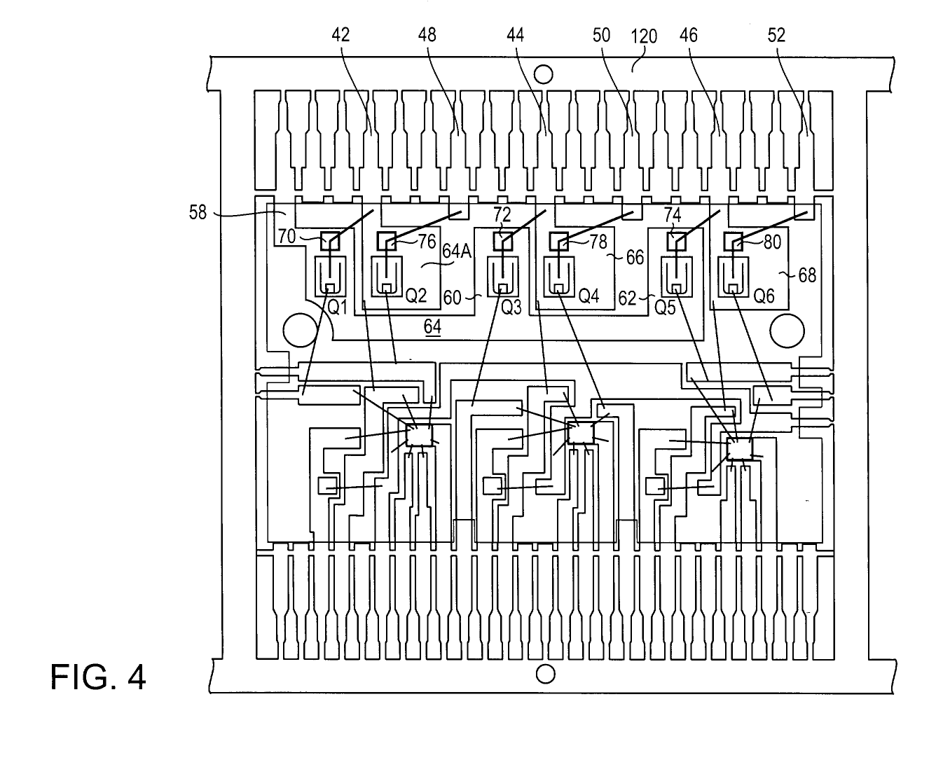

Instead of using an IMS 110 (as in the example of FIG. 3), a metallic lead frame 120 may be used as shown in FIG. 4. FIG. 4 shows that lead structure for the power semiconductor devices Q₁-Q₆ and their associated bootstrap diodes 70, 76, 72, 78, 74, 80 is substantially the same as the pattern shown in FIG. 3.

Also as seen in FIG. 4, the output wire bonds leading from the power devices Q1-Q6 to the corresponding output leads are separated from each other; and preferably are substantially parallel to each other, even if the output wire bonds do not follow a straight path. Thus, the wire bonds connecting the switches Q1-Q6 with their respective bootstrap diodes 70-80 are all substantially parallel to each other. Further, the wire bonds connecting the bootstrap diodes 70-74 to their respective output leads 42-46 are substantially parallel to each other; and the wire bonds connecting the bootstrap diodes 76-80 to their respective output leads 48-52 are also substantially parallel to each other.

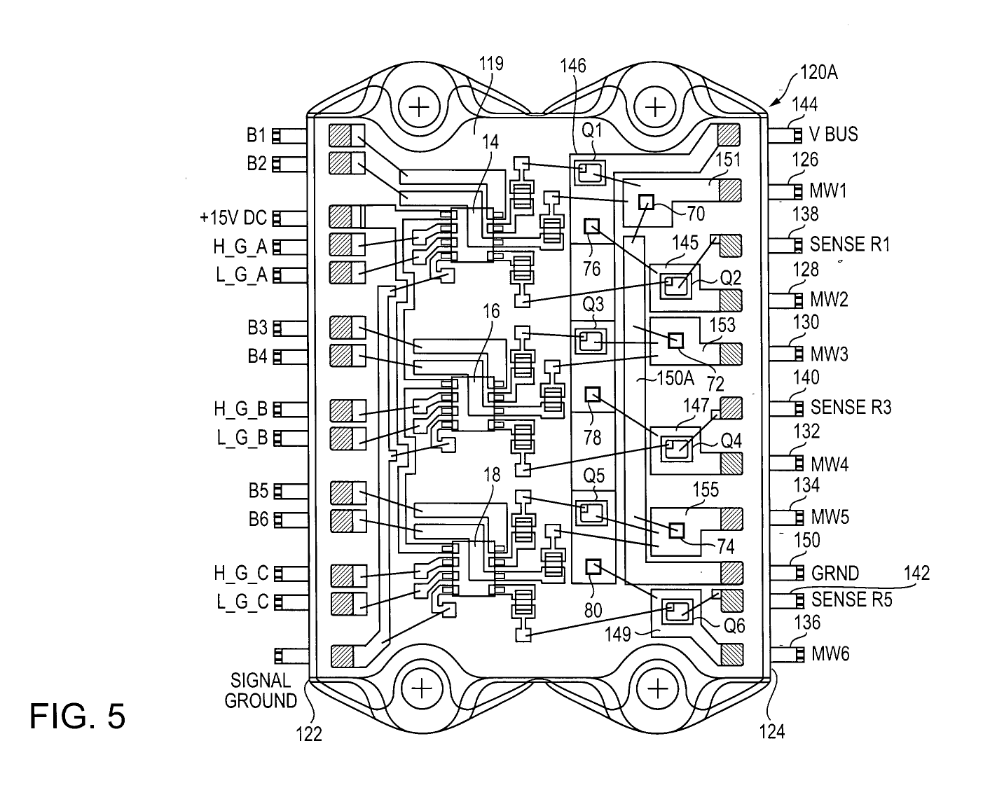

FIG. 5 shows another comparative example of a power module 120A for housing a motor control circuit for controlling a switched-reluctance motor. Power module 120A also includes insulated metal substrate 119, on which power semiconductor driver circuits 14, 16, 18 are disposed. Insulated metal substrate 119 has substantially the same pattern of runners and lands as those shown in FIG. 3 for power semiconductor driver circuit 14, 16, 18. The leads disposed on second side 122 of power module 120A are also the same as those shown in FIG. 3 and described above in respect thereto. On first side 124 of power module 120A, which opposes second side 122, a row of leads is provided. The row of leads includes power leads 126, 128, 130, 132, 134, 136 which connect respectively to motor windings of a switched-reluctance motor (not shown), and sensor leads 138, 140, 142. Bus lead 144 is connected to a common electrical strip 146 disposed on a surface of insulated metal substrate 119. Common electrical strip 146 is substantially parallel to first side 124 of power module 120A and has disposed thereon high-side power semiconductor switches Q₁, Q₃, Q₅ and bootstrap diodes 76, 78, 80 which are associated with low-side power-semiconductor switches Q₂, Q₄, Q₆. Low-side power semiconductor switches Q₂, Q₄, Q₆ are disposed on electrically conductive patches 145, 147, 149 on insulated metal substrate 119, which are connected to power leads 128, 132, 136. Patches 145, 147, 149 are disposed opposite common electrical strip 146. Bootstrap diodes 70, 72, 74 which are associated with high-side power semiconductor switches Q₁, Q₃, Q₅ are disposed on electrically conductive patches 151, 153, 155 on insulated metal substrate 119 also opposing common electrical strip 146. Ground lead 150 is connected to a ground electrical strip 150A which runs parallel to common electrical strip 146. Appropriate electrical connections are made using bond wires as shown in FIG. 5.

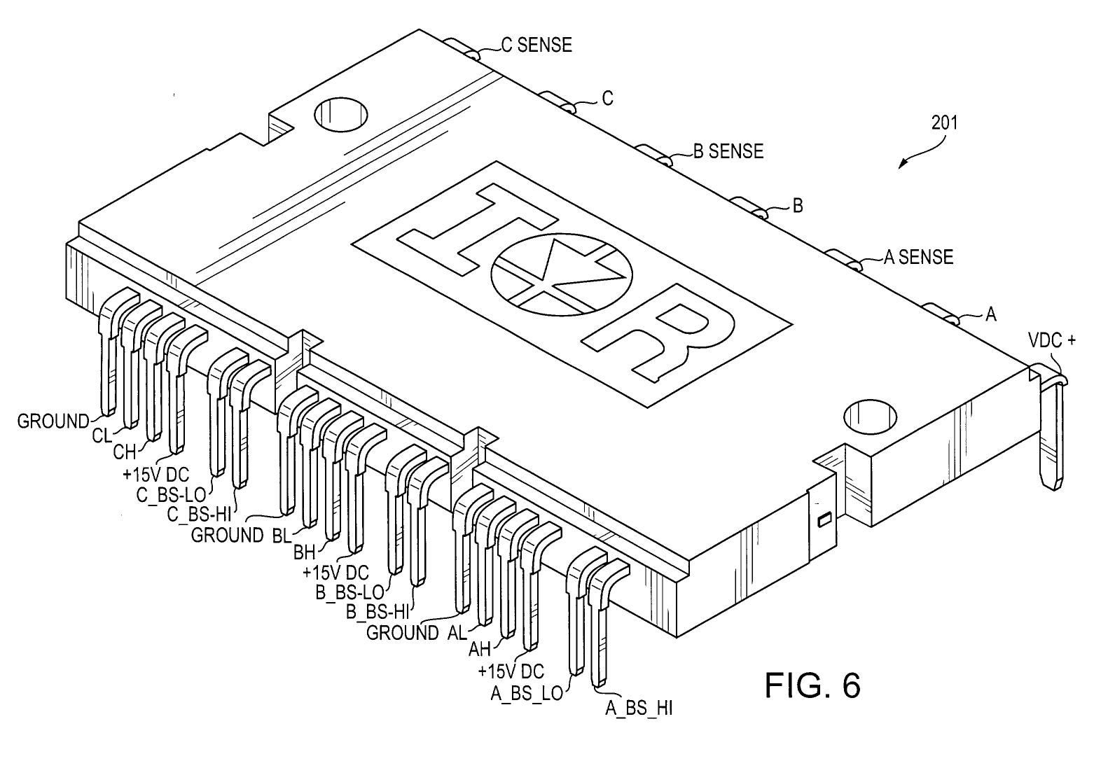

In the power module shown in FIG. 4, the power devices Q1-Q6 advantageously comprise bare die, mounted on the lead frame 120. The lead frame 120 and the various components are then molded, preferably transfer-molded or injection-molded, to form a package. FIG. 6 shows an example of such a package 201, which in this example encloses the circuit of FIG. 4.

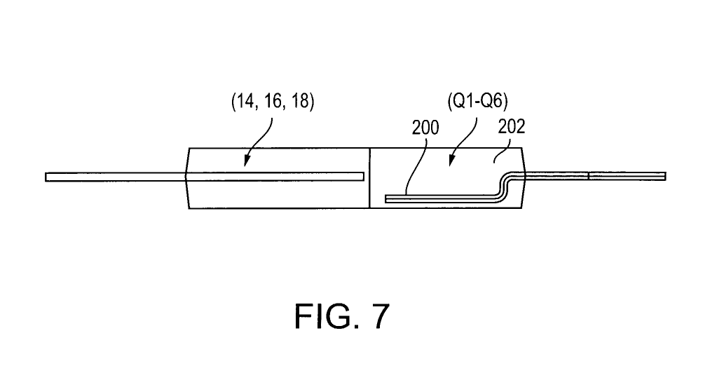

FIG. 7 shows a cross-sectional view of the package 201 shown in FIG. 6. As seen in FIG. 7, as in FIG. 3, a portion of the lead frame 120 holds the drivers 14, 16, 18, while another portion of the lead frame 120 holds the power devices Q₁-Q₆.

In order to improve the thermal dissipation performance of the package, the lead frame portion of power semiconductor switches Q₁-Q₆ may be moved closer to the surface of the package than the lead frame portion on which the drivers 14, 16, 18 are mounted, as shown in FIG. 7. FIG. 7 diagrammatically shows an exemplary lead frame portion 200 which receives a power semiconductor switch e.g., Q₁-Q₆, to be positioned closer to an external surface of package 202, preferably about 0.5 mm or 20 mils, in order to allow better heat dissipation. It should be noted that, in FIG. 7, lead frame portion 200 is spaced from the other portion of the lead frame (which may be similar to the corresponding portions of FIGS. 3, 4 and 5) on which the driver circuits 14, 16, 18 are disposed. The lead frame portion 200 may be similar to the portion of the lead frame 120 in FIG. 4, which portion holds the power devices Q₁-Q₆.

The control side including the drivers 14, 16, 18 could alternatively be mounted on another type of substrate such as a flexible circuit board.

Although the present invention has been described in relation to particular embodiments thereof, many other variations and modifications and other uses will become apparent to those skilled in the art. Therefore, the present invention is not limited by the specific disclosure herein.

We claim:

1. A power module comprising:
a lead frame having a plurality of power switching devices and a plurality of driving devices mounted thereon;
wherein said driving devices control said power switching devices to provide power via first wire bonds to a plurality of output leads, and
wherein said first wire bonds are substantially parallel to each other between said power switching devices and said output leads.

2. A power module as in claim 1, wherein each power switching device includes a power semiconductor device and a diode associated therewith;
wherein said diodes and said power switching devices are interconnected by second wire bonds which are substantially parallel to each other.

3. A power module as in claim 2, wherein said diodes are connected to said output leads by said first wire bonds.

4. A power module as in claim 1, wherein each power switching device includes a power semiconductor device and a diode associated therewith; and
wherein said diodes are connected to said output leads by said first wire bonds.

5. A power module as in claim 1, wherein said power switching devices comprise bare semiconductor die mounted on said lead frame; and
wherein said lead frame and said power switching devices are enclosed in a molded package.

6. A power module as in claim 5, wherein each power switching device includes a power semiconductor device and a diode associated therewith, said power semiconductor device and said diode comprising bare semiconductor die mounted on said lead frame.

7. A power module comprising:
a lead frame having a plurality of power switching devices and a plurality of driving devices mounted thereon;
wherein said power switching devices comprise bare semiconductor die mounted on said lead frame; and
wherein said lead frame and said power switching devices are enclosed in a molded package.

8. A power module as in claim 7, wherein each power switching device includes a power semiconductor device and a diode associated therewith, said power semiconductor device and said diode comprising bare semiconductor die mounted on said lead frame.

9. A method of assembling a power module comprising the steps of:
mounting a plurality of power switching devices and a plurality of driving devices on a lead frame;
connecting said driving devices to said power switching devices; and
connecting said power switching devices via first wire bonds to a plurality of output leads,
wherein said first wire bonds are substantially parallel to each other between said power switching devices and said output leads.

10. A method as in claim 9, wherein each power switching device includes a power semiconductor device and a diode associated therewith;
wherein said diodes and said power switching devices are interconnected by second wire bonds which are substantially parallel to each other.

11. A method as in claim 10, wherein said diodes are connected to said output leads by said first wire bonds.

12. A method as in claim 9, wherein each power switching device includes a power semiconductor device and a diode associated therewith; and
wherein said diodes are connected to said output leads by said first wire bonds.

13. A method as in claim 9, wherein said power switching devices comprise bare semiconductor die mounted on said lead frame; and
further comprising the step of forming a molded package enclosing said lead frame and said power switching devices.

14. A method as in claim 13, wherein said forming step comprises transferor injection-molding said package.

15. A method as in claim 13, wherein each power switching device includes a power semiconductor device and a diode associated therewith, said power semiconductor device and said diode comprising bare semiconductor die mounted on said lead frame.

16. A method of assembling a power module comprising the steps of:
mounting a plurality of power switching devices and a plurality of driving devices on a lead frame;
wherein said power switching devices comprise bare semiconductor die; and
forming a molded package enclosing said lead frame and said power switching devices.

17. A method as in claim 16, wherein each power switching device includes a power semiconductor device and a diode associated therewith, said power semiconductor device and said diode comprising bare semiconductor die mounted on said lead frame.

18. A method as in claim 17, wherein said forming step comprises transferor injection-molding said package.

19. A method as in claim 16, wherein said forming step comprises transferor injection-molding said package.
